(19) United States
(12) Patent Application Publication
(10) Pub. No.: US 2024/0181729 A1
(43) Pub. Date: Jun. 6, 2024

(54) MONITORING OF HEAT PAD ELECTRICAL RESISTANCE IN TIRE REPAIR SYSTEM

(71) Applicant: Fuller Bros. Inc., Clackamas, OR (US)

(72) Inventors: Max E. BUTZ, Mossyrock, WA (US); Duane Allan SARKINEN, Yacolt, WA (US); Timothy C. FULLER, Beavercreek, OR (US)

(21) Appl. No.: 18/551,588

(22) PCT Filed: Jun. 2, 2022
(86) PCT No.: PCT/US22/72734

§ 371 Date: Sep. 20, 2023

Related U.S. Application Data
(60) Provisional application No. 63/196,662, filed on Jun. 3, 2021.

(51) Int. Cl. B29C 73/12; G01R 27/08

(52) U.S. Cl. CPC B29C 73/12; G01R 27/08

(57) ABSTRACT

Disclosed is an off-the-road (OTR) tire repair system. In some embodiments, the OTR tire repair system includes a heat pad; an RFID tag coupled to the heat pad, the RFID tag including a machine-readable medium on which is stored information indicating an electrical flow parameter fault condition for the heat pad; an RFID reader configured to read the information from the RFID tag; and a control panel configured to receive the information from the RFID reader, and the control panel configured to detect, during operation of the heat pad and based on the information, presence of the electrical flow parameter fault condition.

### RELATED APPLICATION

This application claims priority benefit of U.S. patent application Ser. No. 63/196,662, filed Jun. 3, 2021, which is hereby incorporated by reference in its entirety.

### BACKGROUND INFORMATION

Omega Vulcanizing Systems, available from the present applicant, Fuller Bros. Inc. of Clackamas, Oregon, are off-the-road (OTR) tire repair systems employing heat pads and airbags positioned on a tire to cure raw rubber in an injured area of the tire (e.g., typically a giant mining or agricultural equipment tire). A typical OTR tire repair entails the following nine steps. First, the injured area of tire is skived out. Second, the injured area is filled with raw rubber and covered with a repair patch. Third, heat pads are placed on the outside and inside of the tire over the injured area. Fourth, an airbag is placed over the outside heat pad to apply pressure and press it onto the raw rubber. Fifth, the inside of tire is “loaded” with some material (i.e., airbags, load bar or filler pipe) to compensate for outer airbag pressure. Sixth, the airbag and heat pad are secured using ratchet type strapping. Seventh, the airbag is inflated, which is regulated by an Omega control panel. Eighth, the heat pads are powered on, which are also regulated by the Omega control panel. Ninth, cure time is determined by the size of the injured area of tire.

### SUMMARY OF THE DISCLOSURE

The present inventors recognized that the aforementioned repair technique, although conventional in the industry, is susceptible to component failures, primarily originating from a heat pad malfunction. And a heat pad malfunction is likely to cause collateral damage to one or both of the airbag and tire, with a catastrophic scenario ending with a tire catching on fire.

In one aspect, an OTR tire repair system includes a heat pad, an RFID tag coupled to the heat pad, an RFID reader, and a control panel. The RFID tag includes a machine-readable medium on which is stored information indicating an electrical flow parameter fault condition for the heat pad. The RFID reader is configured to read the information from the RFID tag. The control panel is configured to receive the information from the RFID reader. The control panel may then detect, during operation of the heat pad and based on the information, presence of the electrical flow parameter fault condition.

In another aspect, a method of controlling an OTR tire repair system entails reading an RFID tag coupled to a heat pad to obtain information indicating an electrical flow parameter fault condition for the heat pad. The method also entails measuring an electrical flow parameter during operation of the heat pad to determine whether the electrical flow parameter meets or exceeds the electrical flow parameter fault condition for the heat pad.

Additional aspects and advantages will be apparent from the following detailed description of embodiments, which proceeds with reference to the accompanying drawings

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a block diagram of an OTR tire repair system including heat pad electrical resistance monitoring devices.

FIG. 2 is a block diagram of proportional-integral-derivative (PID) controller function blocks, according to one embodiment.

FIG. 3 is a timing diagram for determining ohms of the smart heat pad, according to one embodiment.

FIG. 4 is a flow diagram of a method in accordance with one embodiment.

FIG. 5 is a perspective view of electrical cables and connectors.

FIG. 6 is a perspective view of a tire repair using the smart heat pad.

FIG. 7 is a block diagram of a control panel and an RFID reader/writer.

FIG. 8 is a pictorial view of a user interface presented on a control panel.

### DETAILED DESCRIPTION OF EMBODIMENTS

Before development of heat pad electrical resistance monitoring in OTR tire repair systems, the conventional repair systems experienced an array of heat pad failures, from minor burnouts to multiple components (e.g., heat pads, airbags, and tires) being damaged beyond repair. A root cause analysis was performed.

In testing some heat pads, failures due to a thermal contact issue were observed. Thermal gap-filler material was then deployed, but it was determined that this would be un unworkable long-term solution. Further testing revealed that a majority of heat pad failures were in the outer perimeter of the heat pad, and that most likely these failures were occurring during a so-called ramp-up, i.e., maximum application of amperage until a thermocouple reading is approximately 265° F., at which time amperage is cycled off when the temperature measured by the thermocouple raises above 275° F.

Because each heat pad has a thermocouple wire embedded in the center of the pad and not the outer perimeter, a heat pad experiencing a failure in its outer perimeter may not cause the centrally located thermocouple to react to that failure. A number of destruction tests supported this conclusion. For example, a cutting torch was used to heat the outer perimeter, and the thermocouple was unable to detect that event. Also, another test entailed placing a heat pad in a large vise with the outer corner crimped, which compromised the integrity of the heat pad wires. The crimping of the heat pad wires again was not detected by the thermocouple.

In view of the root cause analysis results, the present inventor developed the disclosed embodiments for monitoring and controlling an entire heat pad in OTR tire repair systems. For example, in contrast to simply measuring the thermocouple as a sole data point in the center of the heat pad, this disclosure describes monitoring an electrical flow parameter (e.g., resistance, in ohms or other parameter such as conductivity) of the embedded heating wire. Detecting issues in the electrical flow parameter provides an additional monitoring point instead of relying solely on the thermocouple as a means to identify a compromised heat pad.

To facilitate monitoring of an electrical flow parameter, this disclosure also describes circuitry configured to inform an OTR tire repair system control panel on a specified parameter range (minimum/maximum ohms) of a particular heat pad.

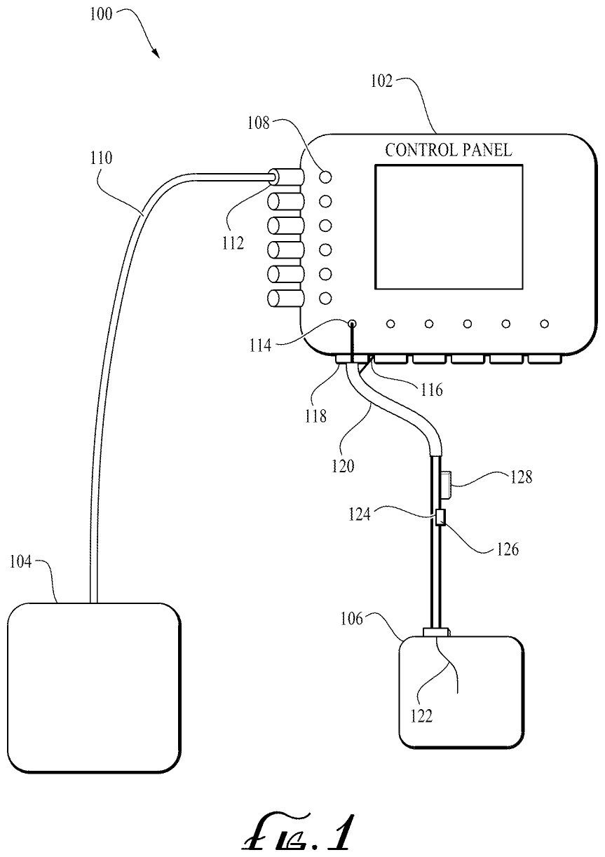

FIG. 1 shows an OTR tire repair system 100, according to one embodiment. OTR tire repair system 100 comprises a control panel 102. Control panel 102 has six sets of air and heat pad connections. As shown in FIG. 1 a first set of air and heat pad connections are used for an airbag 104 and a smart heat pad 106.

To inflate airbag 104, control panel 102 includes an air regulator 108 connected with an air line 110 at an air connection 112 of control panel 102. Air line 110 provides air from control panel 102, through air regulator 108, to airbag 104 so that airbag 104 can be controllably inflated and deflated during a repair. FIG. 1 shows six manual air regulators 108 (each with a corresponding pressure sensor) connected to one main or master pressure regulator (not shown). The master regulator receives air from a source and supplies the six manual air regulators 108 based on the end-user settings. In a manual system, because of the affect that heat has on contained air pressure (increased heat produces increased air pressure), the end-user may monitor and manually adjust the air pressure by either decreasing or increasing the PSI via the manual air regulators 108. In other embodiments described below, an automated pressure regulator system (APRS) is provided for automatic adjustment of pressure.

To power and control smart heat pad 106, control panel 102 includes an RFID control panel connection 114, a thermocouple control panel connection 116, and a power connection 118. Power connection 118 applies power through a power delivery wire 120 to smart heat pad 106. A thermocouple 122 is located inside smart heat pad 106 to provide a signal indicating a temperature of smart heat pad 106. Thermocouple 122 is electrically connected to thermocouple control panel connection 116 through a thermocouple plug 124. Thermocouple 122 includes an RFID tag 126 to store information specific to smart heat pad 106. The information is read and written by an RFID reader/writer 128, which communicates the information to control panel 102 via RFID control panel connection 114.

In some embodiments, the RFID technology associated with smart heat pad 106 and control panel 102 employs an active-type RFID tag (high frequency, 13.56 MHz) available from RFID, Inc. of Aurora, Colorado. In some embodiments, RFID tag 126 is read/written with the following data: tag identification number (UID), heat pad identification number (e.g., identifying heat pad manufacturer), accumulated hours of use or other usage information, manufacturer's specified minimum and maximum ohms, maximum amperage obtained, encrypted accumulated hours of use, and maximum temperature. RFID reader/writer 128 communicates this information with control panel 102 through RFID control panel connection 114. RFID reader/writer 128 includes a CR95HF microchip, which is a 13.56-MHz multi-protocol contactless transceiver IC with SPI and UART serial access, available from STMicroelectronics International N.V. of the Netherlands. RFID reader/writer 128 also includes a PIC16F16 microchip 8-bit microcontroller available from Microchip Technology Inc. of Chandler, Arizona.

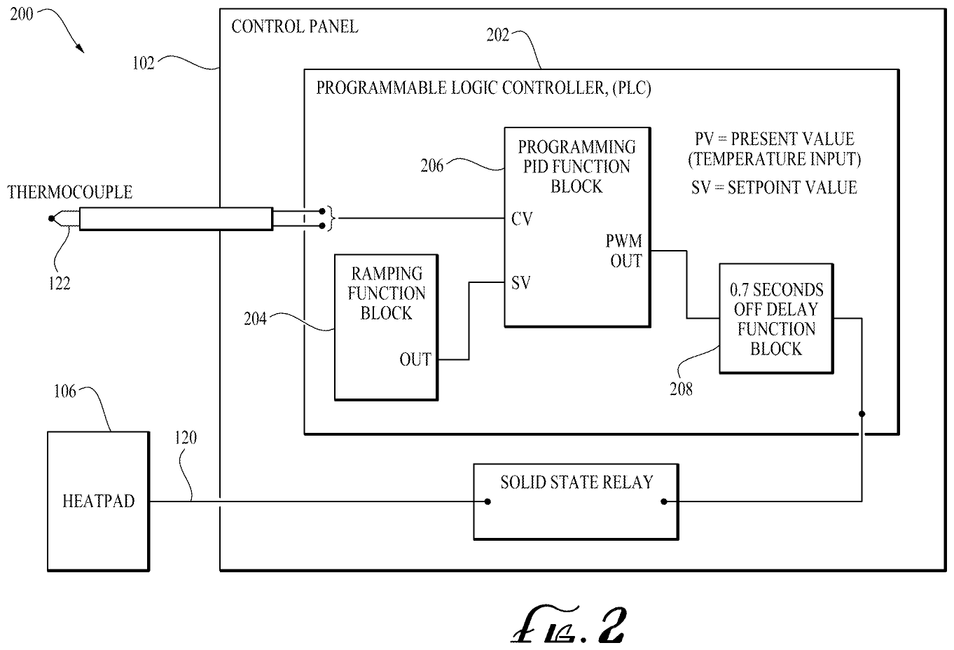

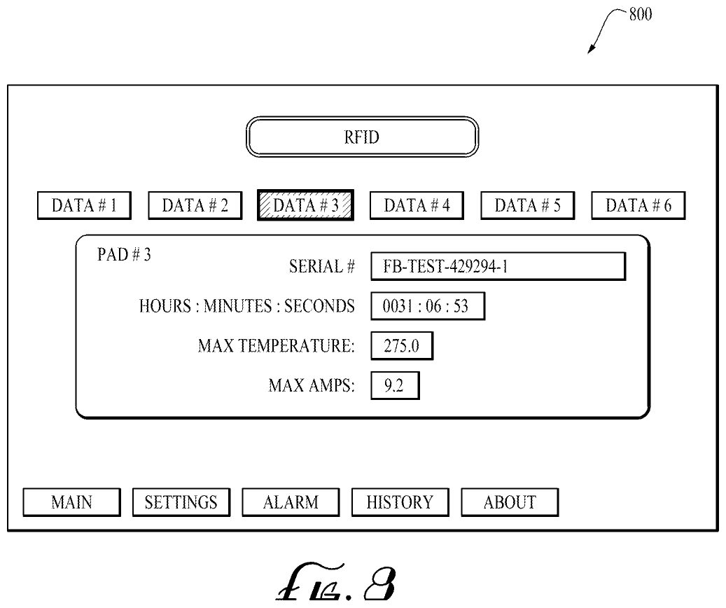

When thermocouple 122 is plugged into a programmable logic controller (PLC) (see e.g., FIG. 2 and FIG. 7), RFID tag 126 that is attached to thermocouple plug 124 is read into the PLC. The information is read in for purposes of gradually applying power to smart heat pad 106 (i.e., a so-called amp ramp algorithm) and removing power in the event of a fault.

To gradually increase the amps delivered to smart heat pad 106 during an initial ramp-up (i.e., increasing the temperature from ambient to 275° F.), a ramp rate is determined from a starting point of 50° F. and raising it to 275° F. in 45 minutes. This equals 12 seconds per degree Fahrenheit. To start the process, an operator pushes a start button on control panel 102. The PLC program saves the current temperature of smart heat pad 106. The saved temperature is transferred to a setpoint of a PID (see, e.g., FIG. 7). A cycle timer is set for 12 seconds and each time the timer times out, the program adds one degree to the PID setpoint. The PID then modulates the cycle time of the power applied to smart heat pad 106, based on the setpoint. This ramp continues until 275° F. (or 135° C.) is reached. (For Celsius, there are 21.6 seconds for each degree.) With the amp ramp algorithm, control panel 102 controls amperage delivered to smart heat pad 106. The gradual ramp up in temperature is performed because, as described previously, thermocouple 122 does not sense temperature at a perimeter of smart heat pad 106 so if there is damage at the perimeter, the gradual ramp up provides an opportunity to sense that damage by measuring ohms before smart heat pad 106 becomes too hot and dangerous.

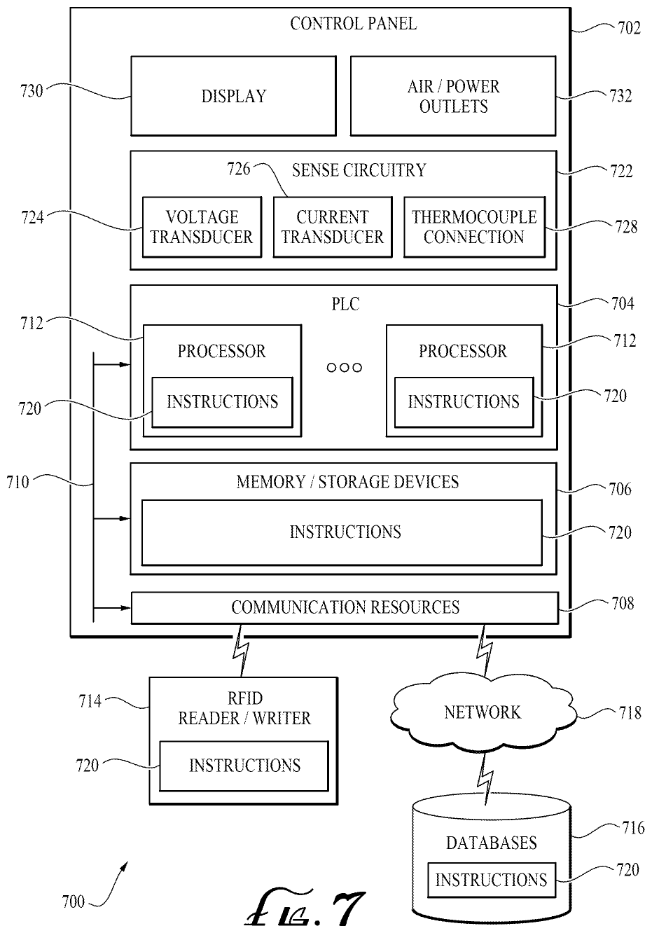

Control panel 102 also removes power in the event of a fault. As mentioned above, the manufacturer's ohm specification, e.g., one value for a low side and one value for a high side, is provided to control panel 102. Specifically, control panel 102 obtains information from RFID tag 126 and references its information for determining an electrical flow parameter fault condition. For instance, the information may include minimum and maximum specified ohm values or a nominal (e.g., middle or average) specified ohm value and a range outside of which there is a fault. During operation, actual ohms of smart heat pad 106 are then measured and compared to the manufacturer's ohm specification. If it is out of specification (i.e., exceedingly low or high), smart heat pad 106 will be shut off and an alarm set. This check is made throughout the whole process of a tire patch cure. Accordingly, in the event measured ohms were to fall out of the manufacturer's recommended minimum/maximum range, control panel 102 would remove power to smart heat pad 106 and thus eliminate the possibility of further damaging smart heat pad 106, airbag 104, or the tire (FIG. 6).

FIG. 2 shows a PLC 202 including a ramping function block 204, programming PID function block 206, and delay function block 208. Function blocks are programming utilities available in PLC software development tools that allow a programmer to perform logic operations. Skilled persons will appreciate, however, that in lieu of or in a addition to the PLC, dedicated logic circuity or other software and associated electronics may be employed to control smart heat pad 106.

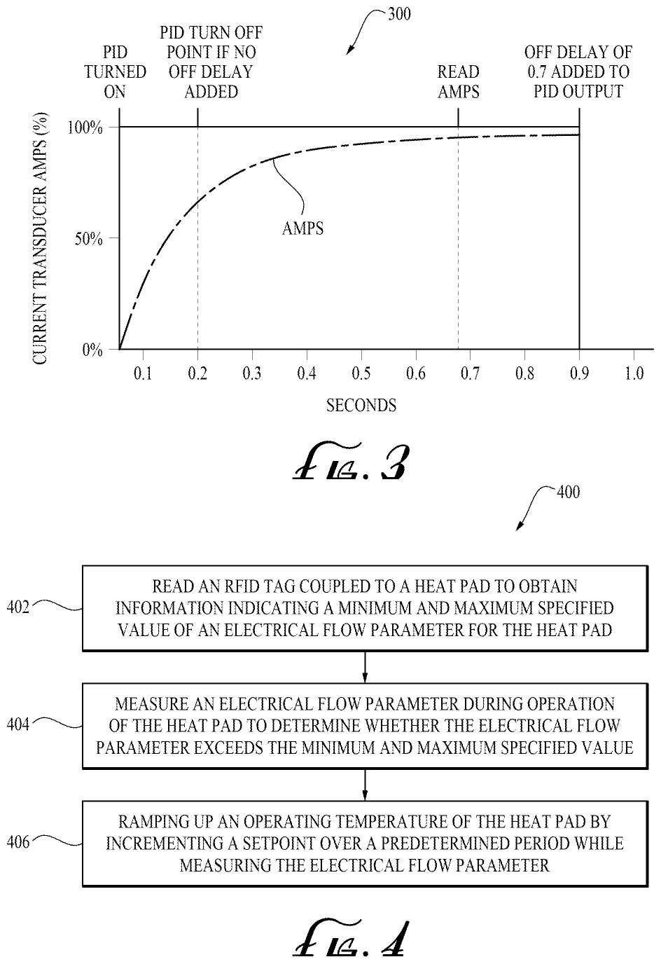

Ramping function block 204 is used to produce the amp ramp described previously. An output of ramping function block 204 and current temperature value of thermocouple 122 are applied as inputs to programming PID function blocks 206. Based on the inputs, programming PID function block 206 generates a pulse width modulated PWM output. The PWM output is applied as an input to delay function block 208, which (as described in connection with FIG. 3) ensures the PWM output actuates power to smart heat pad 106 for a sufficient time to measure ohms.

FIG. 3 shows a timing diagram 300 for measuring ohms of smart heat pad 106. To measure ohms, PLC 202 (FIG. 2) reads voltage and current through transducers (see, e.g., FIG. 7). When current from PID output signal is applied to a current transducer, it will read 95% of full amps in about 0.69 seconds. Thus, the PID output signal is programmed to remain active for at least this amount of time, irrespective of the actual PWM output pulse duration. For instance, the PID output signal can be less than 0.2 seconds due to rapid PWM. To prevent a misread of the amps, an off delay of 0.7 seconds is added to the PID output signal so that it remains on for at least 0.7 seconds.

To calculate the amps, the PLC program waits 0.69 seconds after the PID signal turns on and takes a snapshot of the amps at this time. Since the amps are at about 95% of full value, 5% is added to the amp value for any amp value over 5 amps. Below 5 amps no percentage is added due to the steeper part of the curve. When the PID signal is in the off cycle, and it is off for longer than 3.0 seconds, the amp reading goes to zero. At zero amps, the ohms are not calculated. The manufacturer specifies that there is an additional 3% error in the ohm range due to manufacturing inconsistencies. This 3% error is subtracted from the low ohm specification and added to the high specification. At this point the ohms are calculated from the voltage and the amps. If the ohms are out of range for 45 seconds, then the heat pad is shut down and an alarm is set.

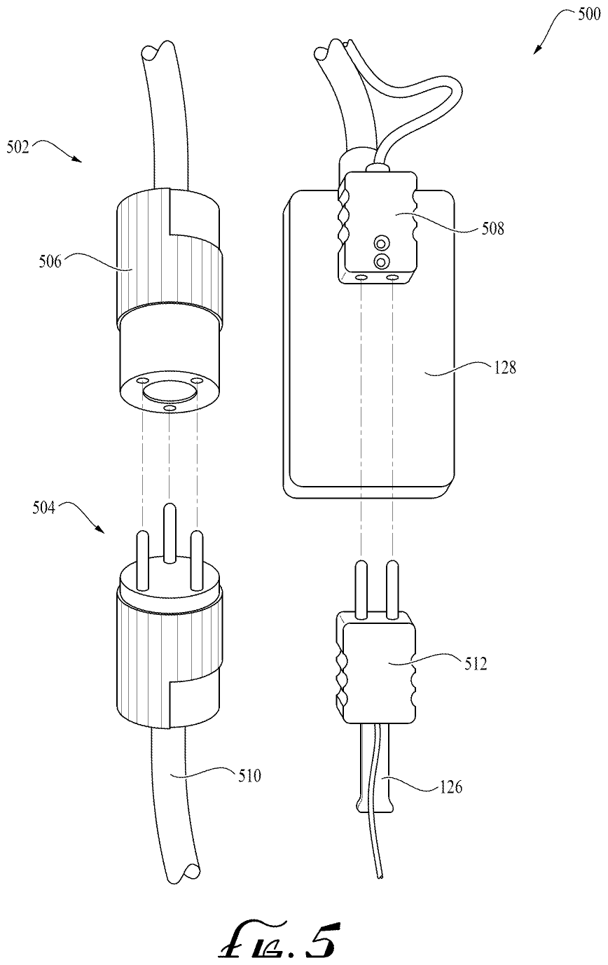

FIG. 4 shows a method 400 of controlling an OTR tire repair system. In block 402, method 400 reads an RFID tag coupled to a heat pad to obtain information indicating a minimum and maximum specified value of an electrical flow parameter for the heat pad. In block 404, method 400 measures an electrical flow parameter during operation of the heat pad to determine whether the electrical flow parameter exceeds the minimum and maximum specified value. In block 406, method 400 ramps up an operating temperature of the heat pad by incrementing a setpoint over a predetermined period while measuring the electrical flow parameter.

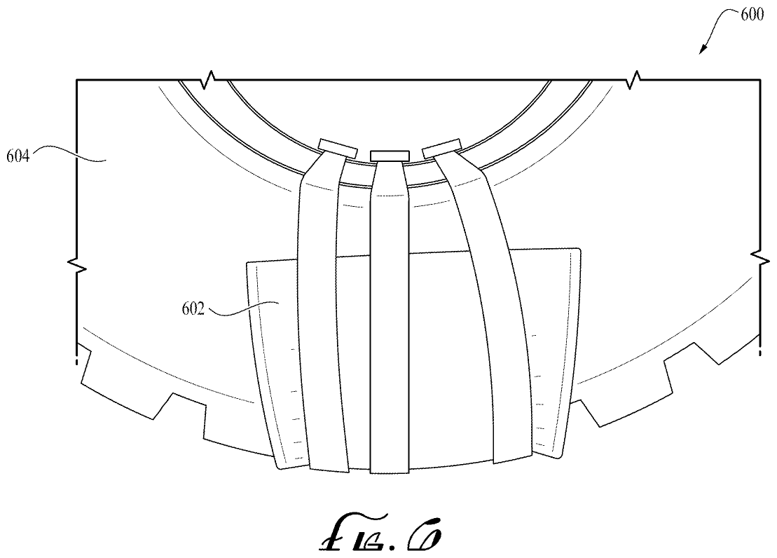

FIG. 5 shows an example of electrical cables and connectors 500 between smart heat pad 106 and control panel 102. Electrical cables and connectors 500 comprise cables to control panel 502 and cables to heat pad 504. Cables to control panel 502 include a power cord 506, a female thermocouple plug 508, and RFID reader/writer 128. Cables to heat pad 504 include a power cord 510, a male thermocouple plug 512, and RFID tag 126.

FIG. 6 shows an example tire repair 600 using OTR tire repair system 100 of FIG. 1. In this example, an airbag 602 is strapped to a side of a tire 604 for earth working equipment. A smart heat pad (not shown) is placed under airbag 602, which applies pressure to the heat pad and rubber that is curing.

FIG. 7 is a block diagram illustrating components 700, according to some example embodiments, able to read instructions from a machine-readable or computer-readable medium (e.g., a non-transitory machine-readable storage medium) and perform any one or more of the methodologies discussed herein. Specifically, FIG. 7 shows a diagrammatic representation of control panel 702 including a PLC 704, one or more memory/storage devices 706, and one or more communication resources 708, each of which may be communicatively coupled via a bus 710.

An example of PLC 704 is a model FC6A-D16P1CEE available from IDEC Corporation of Osaka, Japan. PLC 704 may include, for example, a processor 712. For example, processor 712 may include a central processing unit (CPU), a reduced instruction set computing (RISC) processor, a complex instruction set computing (CISC) processor, an application specific integrated circuit (ASIC), another processor, or any suitable combination thereof.

Memory/storage devices 706 may include main memory, disk storage, or any suitable combination thereof. Memory/storage devices 706 may include, but are not limited to, any type of volatile or non-volatile memory such as dynamic random-access memory (DRAM), static random-access memory (SRAM), erasable programmable read-only memory (EPROM), electrically erasable programmable read-only memory (EEPROM), Flash memory, solid-state storage, etc.

Communication resources 708 may include interconnection or network interface components or other suitable devices to communicate with one or more RFID reader/writer 714 or one or more databases 716 via a network 718. For example, communication resources 708 may include wired communication components (e.g., for coupling via a Universal Serial Bus (USB)), cellular communication components, NFC components, Bluetooth® components (e.g., Bluetooth® Low Energy), Wi-Fi® components, and other communication components.

Instructions 720 may comprise software, a program, an application, an applet, an app, or other executable code for causing at least any of PLC 704 to perform any one or more of the methods discussed herein. Instructions 720 may reside, completely or partially, within PLC 704 (e.g., within the processor's cache memory), memory/storage devices 706, or any suitable combination thereof. Furthermore, any portion of the instructions 720 may be transferred to control panel 702 from any combination of RFID reader/writer 714 or databases 716. Accordingly, the memory of PLC 704, memory/storage devices 706, RFID reader/writer 714, and databases 716 are examples of computer-readable and machine-readable media.

Control panel 102 includes sense circuitry 722, which includes a voltage transducer 724, current transducer 726, and thermocouple connection 728. These components are used to measure ohms and to monitor temperature and amps delivered to a smart heat pad. An example current transducer is an H623-20 (20 amp) or H623-10 (10 amp) available from Veris Industries of Tualatin, Oregon. An example voltage transducer is a VTUH-010-24U-DIN available from NK Technologies of San Jose, California.

Control panel 102 includes a display 730, which may include a human-machine interface (HMI) for controlling and monitoring a tire repair process. An example HMI is shown in FIG. 8. In some embodiments, an HMI with a 9.7-inch screen (part number CMT3092×) is available from Weintek Labs., Inc. of New Taipei City, Taiwan. This HMI provides remote access to control panel 102 so that the end-user could monitor and interact with control panel 102 remotely. It also provides support to remotely troubleshoot and provide updates to control panel 102. And it provides an ability for real-time training to the end-user.

Air/power outlets 732 are also included, as described in connection with FIG. 1. For instance, FIG. 1 shows air regulator 108.

In another embodiment, an APRS is included in control panel 102. For instance, six electro-pneumatic regulators (part number ITV2030-31N2N4) available from SMC

Corporation of Tokyo, Japan, may be used as a substitute for manual air regulators 108 so as to facilitate remote access. Thus, instead of manual control, electro-pneumatic regulators are controlled via PLC 704. The desired PSI is set by the end-user via the GUI. For instance, the end-user could set the PSI at 27, which sets the initial PSI of airbag 104 (FIG. 1) at 27 PSI. As the temperature of smart heat pad 106 (FIG. 1) increases, so too does the PSI of airbag 104, such that PLC 704 adjusts the corresponding electro-pneumatic regulator to decrease PSI. Conversely, if an airbag had only 26 PSI of pressure, then PLC 704 would direct the corresponding electro-pneumatic regulator to increase the PSI to 27.

FIG. 8 shows a display 800 of control panel 102, according to one embodiment. In this example, display 800 shows RFID information stored for a particular RFID tag 126. After a cure cycle is shut down by a user, faults, or ends the cycle for any reason, the PLC checks to see if the highest amp value in this cycle is higher than the RFID recorded amp value. If so, the new highest value is recorded to RFID tag 126. If the ohms remain in the recommended minimum/maximum range and the cure completes successfully, then the following data is written back to RFID tag 126: accumulated hours of use, maximum temperature, and maximum amps.

Display 800 also shows an indicator for various panel interface alarms. The alarms include low air pressure, high temperature, low temperature, heat pad not heating up sufficiently fast, heat pad ohms out of factory specifications, and temperature sensor disconnected.

Skilled persons will appreciate that many changes may be made to the details of the above-described embodiments without departing from the underlying principles of the invention. The scope of the present invention should, therefore, be determined only by the following claims and equivalents.

1. An off-the-road (OTR) tire repair system, comprising:
a heat pad;
an RFID tag coupled to the heat pad, the RFID tag including a machine-readable medium on which is stored information indicating an electrical flow parameter fault condition for the heat pad;
an RFID reader configured to read the information from the RFID tag; and
a control panel configured to receive the information from the RFID reader, and the control panel configured to detect, during operation of the heat pad and based on the information, presence of the electrical flow parameter fault condition.

2. The tire repair system of claim 1, further comprising an RFID writer to write heat pad usage information to the RFID tag.

3. The tire repair system of claim 1, in which the electrical flow parameter fault condition is a resistance value that is less than or equal to a minimum specified value.

4. The tire repair system of claim 1, in which the electrical flow parameter fault condition is a resistance value that is greater than or equal to a maximum specified value.

5. The tire repair system of claim 1, in which the electrical flow parameter fault condition is a conductance value that is less than or equal to a minimum specified value.

6. The tire repair system of claim 1, in which the electrical flow parameter fault condition is a conductance value that is greater than or equal to a maximum specified value.

7. The tire repair system of claim 1, in which information includes a minimum specified value and a maximum specified value of an electrical flow parameter.

8. The tire repair system of claim 7, in which the electrical flow parameter is resistance or conductance.

9. The tire repair system of claim 1, in which the information includes a nominal specified value and a range outside of which the electrical flow parameter fault condition is present.

10. A method of controlling an off-the-road (OTR) tire repair system, the method comprising:
reading an RFID tag coupled to a heat pad to obtain information indicating an electrical flow parameter fault condition for the heat pad; and
measuring an electrical flow parameter during operation of the heat pad to determine whether the electrical flow parameter meets or exceeds the electrical flow parameter fault condition for the heat pad.

11. The method of claim 10, further comprising ramping up an operating temperature of the heat pad by incrementing a setpoint over a predetermined period while measuring the electrical flow parameter.

12. The method of claim 10, further comprising determining the electrical flow parameter is less than or equal to a minimum specified value.

13. The method of claim 10, further comprising determining the electrical flow parameter is greater than or equal to a maximum specified value.

14. The method of claim 10, further comprising generating a user alert in response to determining the electrical flow parameter meets or exceeds the electrical flow parameter fault condition.

15. The method of claim 14, further comprising automatically stopping power delivery to the heat pad in response to the determining.

16. The method of claim 10, further comprising writing heat pad usage information to the RFID tag.
